(19) United States
(12) Patent Application Publication
(10) Pub. No.: US 2026/0271449 A1
(43) Pub. Date: Sep. 10, 2026

(54) DIRECT AND SELECTIVE MASS TRANSFER PROCESS FOR MICROLED DISPLAY FABRICATION

(71) Applicant: Applied Materials, Inc., Santa Clara, CA (US)

(72) Inventors: Peiwen LIU, Fremont, CA (US); Jeffrey L. FRANKLIN, Santa Clara, CA (US); Fabio PIERALISI, Aschaffenburg (DE); Kai DING, Cupertino, CA (US); Uma SRIDHAR, Sunnyvale, CA (US); Joshua DENNEY, Prunedale, CA (US); Raanan ZEHAVI, Santa Clara, CA (US); Mingwei ZHU, San Jose, CA (US); Hou T. NG, Campbell, CA (US); Nag B. PATIBANDLA, Santa Clara, CA (US)

(21) Appl. No.: 19/167,296

(22) PCT Filed: Mar. 18, 2024
(86) PCT No.: PCT/US2024/020410

§ 371 Date: Sep. 19, 2025

Related U.S. Application Data
(60) Provisional application No. 63/453,826, filed on Mar. 22, 2023.

(51) Int. Cl. H10H 29/03; H10H 29/01; H10H 29/24

(52) U.S. Cl. CPC H10H 29/03; H10H 29/0363; H10H 29/24

(57) ABSTRACT

Described herein are devices and methods for creating devices including a backplane, the backplane includes a plurality of backplane electrodes where each backplane electrode includes a first material. A plurality of micro-LEDs having a plurality of micro-LED electrodes, each micro-LED electrode including a second material, where each micro-LED electrode is bonded to each backplane electrode with an alloy of the first material and the second material therebetween. The device further includes a plurality of subpixel isolation (SI) structures formed over the backplane, the SI structures defining wells of subpixels, each well including a respective micro-LED between adjacent SI structures, and the subpixels having a color conversion material disposed in the wells.

### BACKGROUND

### Field

Embodiments of the present disclosure generally relate to LED pixels and methods of fabricating LED pixels.

### Description of the Related Art

A light emitting diode (LED) panel uses an array of LEDs, with individual LEDs providing the individually controllable pixel elements. Such an LED panel can be used for a computer, touch panel device, personal digital assistant (PDA), cell phone, television monitor, and the like. An LED panel that uses micron-scale LEDs based on III-V semiconductor technology (also called micro-LEDs) would have a variety of advantages as compared to organic light emitting diodes (OLEDs), e.g., higher energy efficiency, brightness, and lifetime, as well as fewer material layers in the display stack which can simplify manufacturing. However, there are challenges to the fabrication of micro-LED panels.

The process of transferring of micro-LEDs to a backplane generally is a cumbersome procedure. This process can result in poor light-up yield, thermal instability, non-uniformity, and high costs. Therefore, there is a need for an improved micro-LED panel and method of fabricating micro-LED panels.

### SUMMARY

Embodiments of the present disclosure generally relate to LED pixels and methods of fabricating LED pixels.

In one embodiment, a device is disclosed. The device includes a backplane having a plurality of backplane electrodes, each backplane electrode comprising a first material. The device also includes a plurality of micro-LEDs having micro-LED electrodes, each micro-LED electrode is bonded to each backplane electrode with an alloy of the first material and the second material therebetween. The device further includes a plurality of sub-pixel isolation (SI) structures disposed over the backplane, the SI structures define wells of sub-pixels, each well includes a respective micro-LED between adjacent SI structures, and the subpixels having a color conversion material disposed in the wells.

In another embodiment, a method is disclosed. The method includes aligning a transfer piece with a receiving piece. The receiving piece includes a bonder stage, a backplane disposed on the bonder stage, and backplane electrodes disposed on the backplane. The transfer piece includes a bonder head, a plate coupled to the bonder head, micro-LEDs coupled to the plate, and micro-LED electrodes coupled to each of the micro-LEDs. The method further includes heating the transfer piece to a first temperature and heating the receiving piece to second temperature, applying pressure to the transfer piece, alloying the backplane electrodes with the micro-LED electrodes, decreasing the second temperature, applying a clamp to the transfer piece, applying a laser to the clamp, and vaporizing an interface between the plate and the micro-LEDs.

In another embodiment, a method is disclosed. The method includes aligning a transfer piece with a receiving piece. The receiving piece includes a bonder stage, a backplane disposed on the bonder stage, and backplane electrodes disposed on the backplane where the backplane electrodes include a first material. The transfer piece includes a bonder head, a plate coupled to the bonder head, micro-LEDs coupled to the plate, and micro-LED electrodes coupled to each of the micro-LEDs where the micro-LED electrodes include a second material. The method further includes heating the transfer piece to a first temperature and heating the receiving piece to second temperature, applying pressure to the transfer piece, forming an alloy of the first material and the second material between the backplane electrodes and the micro-LED electrodes, decreasing the second temperature, applying a clamp to the transfer piece, applying a laser in a symmetric pattern to the clamp, and vaporizing an interface between the plate and the one or more micro-LEDs.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a cross-sectional view of a pixel according to embodiments.

FIG. 2 is a flow diagram of a method of fabricating a pixel according to embodiments.

FIGS. 3A-3J are schematic, cross-sectional views of a backplane during a method according to embodiments.

### DETAILED DESCRIPTION

Embodiments of the present disclosure generally relate to LED pixels and methods of fabricating LED pixels. In a micro-LED display device, micro-LEDs are connected to a backplane via a bonding process where backplane electrodes are bonded with micro-LED electrodes. The process of transferring micro-LEDs described herein utilizes fewer steps than other processes of transferring micro-LEDs. Other processes require utilizing a greater number of steps, resulting in a cumbersome transfer process. This cumbersome process can also result in thermal instability, non-uniformity in the micro-LED transfer, and higher costs. By utilizing fewer steps, the process described herein increases the light-up yield of the micro-LEDs, requires fewer materials, and leads to a more uniform in the micro-LED placement. This method also allows for selective micro-LED transfer to a low density backplane. This method also allows for the formation of an alloy between the backplane electrodes and micro-LED electrodes by bonding a first material of the backplane electrodes and a second material of the micro-LED electrodes via temperature control. This alloy provides a more secure bonding as well as thermal stability between the backplane electrodes and micro-LED electrodes while maintaining electrical conductivity.

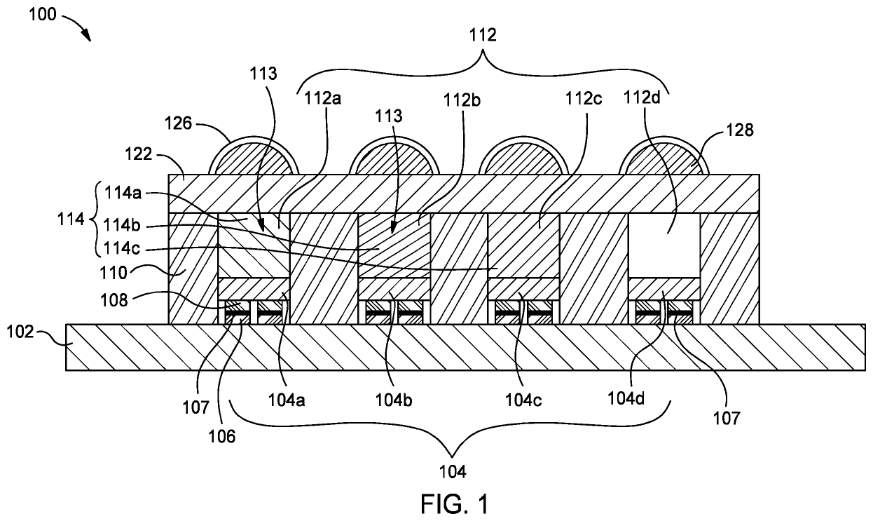

FIG. 1 is a cross-sectional view of a pixel 100. The pixel 100 includes at least three micro-LEDs 104 disposed on a backplane 102. The micro-LEDs 104 are integrated with backplane circuitry so that each micro-LED 104 can be individually addressed. For example, the circuitry of the backplane can include a TFT active matrix array with a thin-film transistor and a storage capacitor (not illustrated) for each micro-LED 104, column address and row address lines, column and row drivers, to drive the micro-LEDs 104. Alternatively, the micro-LEDs 104 can be driven by a passive matrix in the backplane circuitry. The backplane 102 can be fabricated using conventional complementary metal-oxide silicon (CMOS) process. The micro-LEDS 104 are connected to the backplane 102 via backplane electrodes 106 and micro-LED electrodes 108. At the interface of the backplane electrodes 106 and the micro-LED electrodes 108, is an alloy 107 of the two electrode materials.

In certain embodiments the backplane electrodes 106 include a first metal of a first material. The first material includes, but is not limited to, gold, indium, tin, silver, aluminum, platinum, or combinations thereof. In certain embodiments, the micro-LED electrodes 108 include a second metal of a second material. The second material includes, but is not limited to, gold, silver, aluminum, platinum, indium, or combinations thereof. In certain embodiments, the first material and the second material are different. An alloy 107 of the first material and the second material is formed from the method described herein. The alloy 107 bonds the backplane electrodes 106 to the micro-LED electrodes 108 to secure the micro-LEDs 104 to the backplane 102. In certain embodiments, the backplane electrodes 106 include indium and the micro-LED electrodes 108 include gold to form the alloy 107 of indium and gold. In other embodiments, the backplane electrodes 106 may include gold and the micro-LED electrodes 108 may include indium to form an alloy 107 of gold and indium. In certain embodiments, the alloy 107 has a ratio of the first material to the second material (i.e., first material:second material). The ratio of first material to second material is about 1:3 to about 3:1. The ratio of first material to second material depends on the material used to form the alloy 107. Each micro-LED 104 configured to emit UV light in a first wavelength range. The UV light may be white light. The micro-LEDs 104 may be LEDs.

SI structures 110 are disposed over, and in some embodiments on, the backplane 102. The adjacent SI structures 110 define the respective well 113 of at least three sub-pixels 112. A micro-LED 104 is disposed in each well 113 between the adjacent SI structures 110. Each well 113 has a width from about 0.5 μm to about 40 μm, such as about 2 μm to about 30 μm. The SI structures 110 have a width from about 0.1 μm to about 15 μm such as 1 μm to 10 μm. The SI structures 110 may include organic material, such as epoxy-based photoresist.

The sub-pixels 112 include a first sub-pixel 112a with a red color conversion material 114a disposed in the well 113 of the first sub-pixel 112a, a second sub-pixel 112b with a blue color conversion material 114b disposed in the well 113 of the second sub-pixel 112b, and a third sub-pixel 112c with a green color conversion material 114c disposed in the well 113 of the third sub-pixel 112c. When a micro-LED 104a of the first sub-pixel 112a is turned on the red color conversion material 114a will convert the light emitted from micro-LED 104a into red light. When a micro-LED 104b of the second sub-pixel 112b is turned on the blue color conversion material 114b will convert the light emitted from micro-LED 104b into blue light. When a micro-LED 104c of the third sub-pixel 112c is turned on the green color conversion material 114c will convert the light emitted from micro-LED 104c into green light. In one embodiment, the pixel 100 includes a fourth sub-pixel 112d. As shown in FIG. 1, the fourth sub-pixel 112d does not include a color conversion material, i.e., color-conversion-layer-free. In some embodiments, the fourth sub-pixel 112d may be later filled with a color conversion material 114 (e.g., a red, green, blue, violet, etc. color conversion material). In another embodiment, the fourth sub-pixel 112d includes a sacrificial material (not shown). In other embodiments, the at least three sub-pixels 112 include the same color conversion material. The fourth sub-pixel 112d may be later filled with a color conversion material 114.

In some embodiments, the color conversion material 114 may include quantum dots (QDs). The quantum dots may be sized to produce wavelengths corresponding to different colors. In one embodiment, the red color conversion material 114a may include quantum dots approximately 6 nm in size. The blue color conversion material 114b may include quantum dots approximately 4 nm in size. The green color conversion material 114c may include quantum dots approximately 2 nm in size. In other embodiments, the color conversion material 114 may include nanostructures, photoluminescent materials, or organic substances.

An encapsulation layer 122 is disposed over, and in some embodiments directly on, a top surface of the SI structures 110 and the sub-pixels 112. The encapsulation layer 122 prevents reactions between the color conversion material 114 and other materials in an ambient environment. The encapsulation layer 122 has a thickness from 10 nm or less and is one of a metal layer, a metal oxide layer, or a silicon containing layer. The encapsulation layer includes, but is not limited to, aluminum oxide, titanium oxide, silicon nitride, tantalum (Ta) hafnium (Hf), tantalum oxide, hafnium oxide, titanium (Ti), aluminum (Al), chromium (Cr), copper (Cu), tungsten (W), zirconium (Zr), or a combination thereof. The encapsulation layer 122 may be deposited using a physical vapor deposition (PVD) process, chemical vapor deposition (CVD), or atomic layer deposition (ALD). The PVD process may include pulsed laser deposition (PLD), thermal evaporation, or electron beam evaporation PVD (EBPVD).

In some embodiments, the pixel 100 includes micro-lenses 128 disposed on the encapsulation layer 122 and over each of the wells 113 of the sub-pixels 112. In some embodiments, a passivation layer 126 is disposed on the micro-lenses 128. In other embodiments, the micro-lenses 128 may be made of a resist material such as photoresist material that blocks UV light.

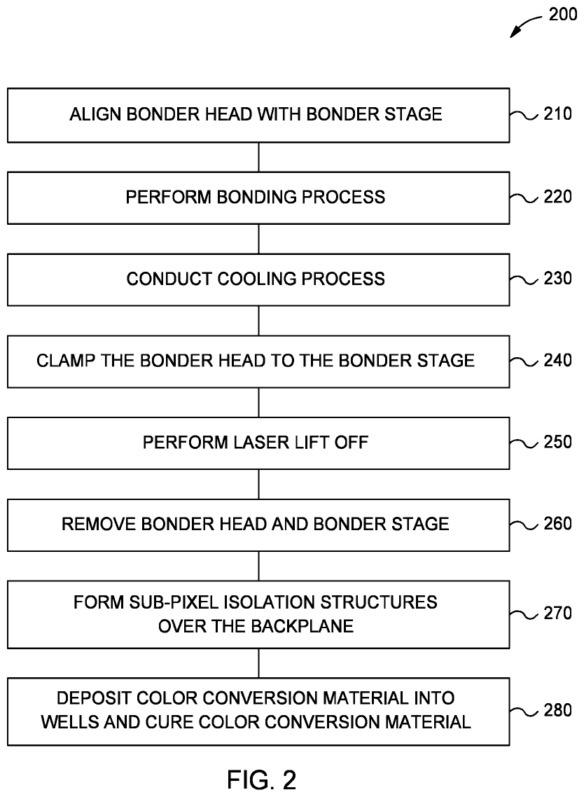

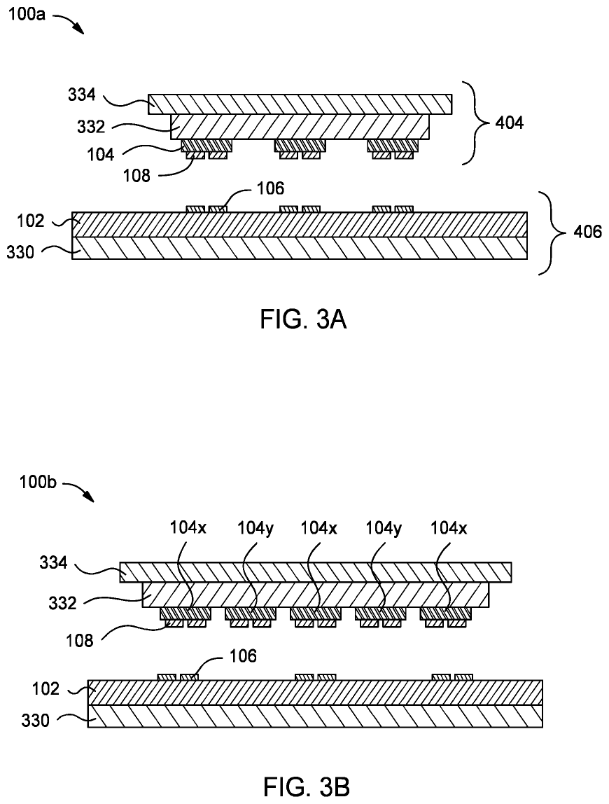

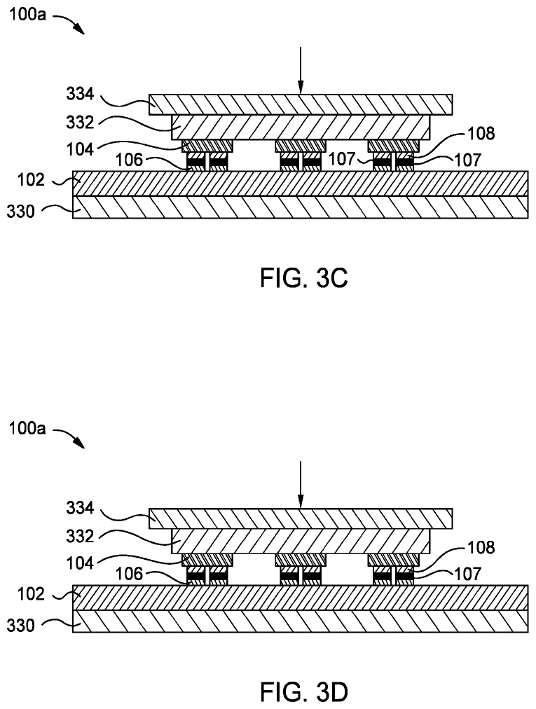

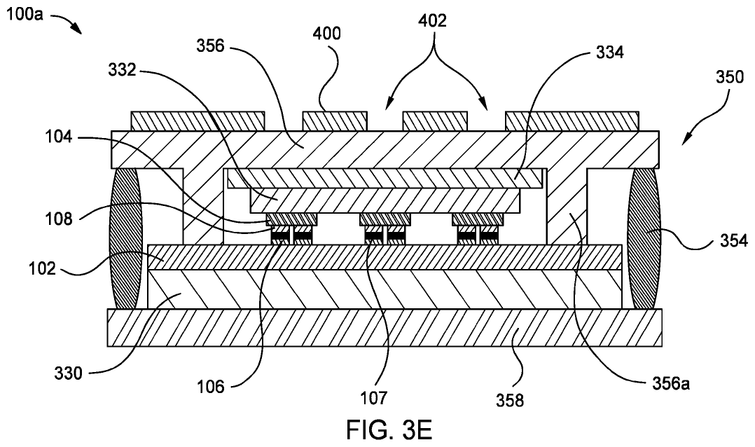

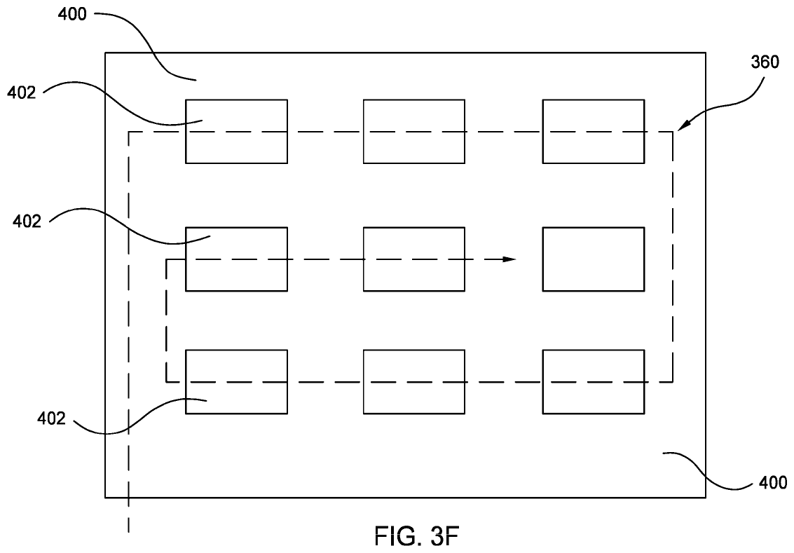

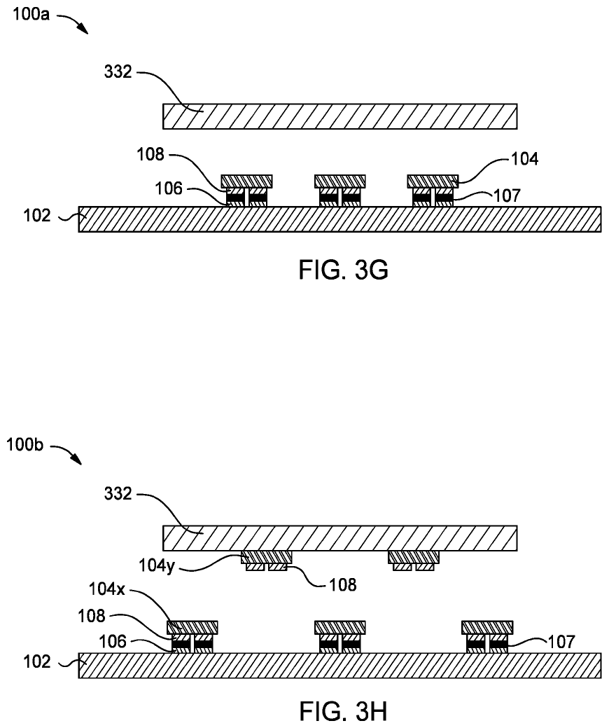

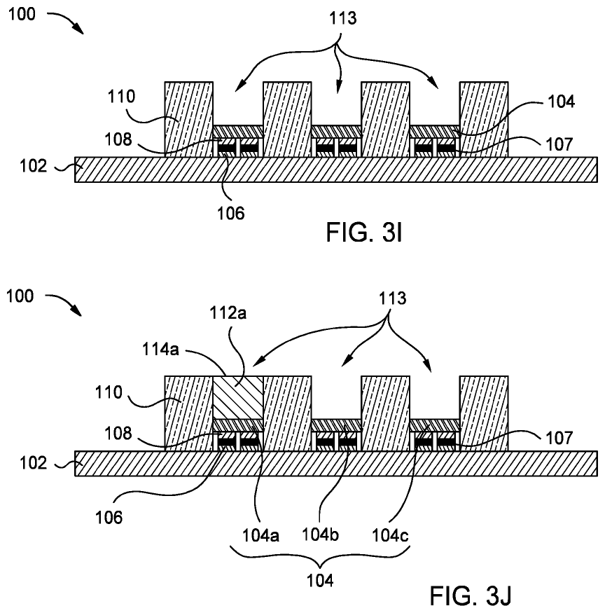

FIG. 2 is a flow diagram of a method 200 of fabricating a pixel 100 according to embodiments. The method 200 includes thermally bonding the backplane electrodes 106 and the micro-LED electrodes 108 to connect the micro-LEDs 104 to the backplane 102 and applying a laser to remove the plate 332 from the micro-LEDs 104. FIGS. 3A-3J are schematic, cross-sectional views of a backplane 102 during the method 200 according to embodiments.

FIG. 3A shows a backplane 102 having a first electrode arrangement 100a. FIG. 3B shows a backplane 102 having a second electrode arrangement 100b. The pixel 100 may have either the first electrode arrangement 100a or the second electrode arrangement 100b. The method 200 utilizes a receiving piece 406 and a transfer piece 404. The receiving piece 406 includes a bonder stage 330, a backplane 102 disposed on the bonder stage 330, and one or more backplane electrodes 106 disposed on the backplane 102. The transfer piece 404 includes a bonder head 334, a plate 332 coupled to the bonder head 334, one or more micro-LEDs 104 coupled to the plate 332 at an interface, and one or more micro-LED electrodes 108 coupled to one or more of the micro-LEDs. In certain embodiments, the micro-LEDs 104 may be grown on the plate 332 by a metal-organic chemical vapor deposition process. The plate 332 is attached to a bonder head 334. In some embodiments, the plate 332 may be silicon (Si), silicon carbide (SiC), aluminum nitride (AlN), gallium nitride (GaN), sapphire, or combinations thereof. In some embodiments, the plate 332 may be sapphire.

In the first electrode arrangement 100a, as shown in FIG. 3A, the number of backplane electrodes 106 is the same as the number as micro-LED electrodes 108. When the number of backplane electrodes 106 and micro-LED electrodes 108 is equivalent, each of the micro-LED electrodes 108 is aligned with the backplane electrodes 106. In the second electrode arrangement 100b, as shown in FIG. 3B, the number of micro-LED electrodes 108 is greater than the number of backplane electrodes 106. When the number of backplane electrodes 106 and micro-LED electrodes 108 are not equivalent, at least one of the micro-LED electrodes 108 are aligned with the backplane electrodes 106. As illustrated by FIG. 3B, micro-LEDs 104x align with respective backplane electrodes 106, and micro-LEDS 104y do not align with any backplane electrodes 106. In some embodiments, the backplane electrodes 106 and the micro-LED electrodes 108 may be aligned via optical instruments.

At operation 210, the micro-LED electrodes 108 are aligned with the backplane electrodes 106. In FIGS. 3A-3B, two micro-LED electrodes 108 are shown for each micro-LED 104. In other embodiments, each micro-LED may have more or fewer micro-LED electrodes 108. At operation 210, the bonder head 334 is heated to a temperature T1. In some embodiments, T1 may be about 40° C. and about 80° C. The bonder stage 330 is heated to a temperature T2. In some embodiments T2 may be about 150° C. and about 300° C. In some embodiments, the temperature T2 is based on the melting point of the first material of the backplane electrodes 106. In other embodiments, the temperature T2 is based on the coefficient of thermal expansion (CTE) of the substrate.

The first material for the backplane electrodes 106 may be chosen based on the material having a lower melting point than the second material of the micro-LED electrodes 108. The backplane electrodes 106 may have a lower melting point than the micro-LED electrodes 108 because the backplane 102 generally has a lower CTE than the plate 332. In some embodiments, the backplane 102 has a CTE on the order of about 10⁻⁷/° C. and the plate 332 has a CTE on the order of about 10⁻⁶/° C. In some embodiments, the melting point of the backplane electrodes 106 may be about 120° C. and about 180° C. In certain embodiments the backplane electrodes 106 include a first metal of a first material. The first material includes, but is not limited to, gold, indium, tin, silver, aluminum, platinum, or combinations thereof. In certain embodiments, the micro-LED electrodes 108 include a second metal of a second material. The second material includes, but is not limited to, gold, silver, aluminum, platinum, indium, or combinations thereof. A second material for the micro-LED electrodes 108 may be chosen based on the desired metallurgical properties of the electrodes. In some embodiments, the metallurgical properties desired in the alloy 107 may be a strong adhesion property and/or a low electrical resistance. In certain embodiments, the first material and the second material are different. In some embodiments, the alloy 107 is an indium-gold alloy where the first material is indium and the second material is gold. An indium-gold alloy may be utilized because gold has a melting point of more than 200° C. above the melting point of indium. This higher melting point results in a more stable connection between the micro-LED 104 and the backplane 102 during the rest of the method 200.

At operation 220, the bonding process is performed by applying a pressure, to the bonder head 334. Applying pressure allows for the alloy 107 to uniformly form between each backplane electrode 106 and micro-LED electrode 108. As shown in FIG. 3C, the backplane electrodes 106 and micro-LED electrodes 108 come in contact. As a result of the temperature T2 of the bonder stage 330 and the pressure, P, the backplane electrodes 106 and the micro-LED electrodes 108 bond by forming an alloy 107. In certain embodiments, the alloy 107 has a ratio of the first material to the second material. The ratio of first material to second material is about 1:3 to about 3:1 (i.e., first material:second material). The ratio of first material to second material depends on the material used to form the alloy 107. The pressure facilitates the alloy 107 formation between the micro-LED electrodes 108 and the backplane electrodes 106. The pressure may be about 100 psi and about 600 psi. Operation 220 may be performed for a set period of time between 0.5 minutes and 10 minutes. For example, in certain embodiments, operation 220 may be performed for a set period of time between about 0.5 minutes and about 2 minutes.

The bonder stage 330 is cooled in operation 230. As shown in FIG. 3D, temperature T2 is cooled to temperature T1. In some embodiments, the temperature T2 may be reduced gradually to avoid damage to the micro-LEDs 104. In some embodiments, the reduction of the temperature T2 may be modeled approximately by a step function. In other embodiments, the reduction of the temperature T2 may be modeled approximately by a linear function with a slope ranging from 5K/s to 30K/s. In other embodiments, the temperature T2 may be reduced as a function of any equation. The temperature T2 may be reduced via cooling channels (not shown) within the bonder stage 330. The gaseous or liquid coolant may be flowed through the cooling channels. The gaseous coolant may be air, oxygen, inert gas, or combinations thereof. The liquid coolant may be water, alcohol, or combinations thereof.

In operation 240, a clamp 350 is applied to the bonder stage 330 and the bonder head 334. As shown in FIG. 3E, the clamp includes a clamping plate 356, a vacuum sealing O-ring 354, a mask 400, and a vacuum chuck 358. The vacuum chuck 358 functions to pull the clamping plate 356 towards the vacuum chuck 358. The clamping plate 356 includes two or more spacers 356a that limit the compression from the vacuum chuck 358. In some embodiments, the force of the vacuum chuck 358 is sufficient to compress the vacuum sealing O-rings 354 and create a vacuum seal. The clamp 350 functions to hold the bonder head 334 and the bonder stage 330 in place during subsequent processing. The clamp 350 prevents strain on the pixel 100 during operation 250. Strain on the pixel 100 may cause delamination. The clamp 350 secures the backplane electrodes 106 and micro-LED electrodes 108 and the plate 332 during operation 250. The mask 400 is over the clamping plate 356. The mask 400 creates channels 402 over the clamping plate 356. The channels 402 are formed over the micro-LEDS 104.

In operation 250, a laser (not shown) is applied to the clamping plate 356 shown in FIG. 3E. Operation 250 may alternatively be referred to as laser lift off. In some embodiments, the laser may be applied in the pattern 360 illustrated in FIG. 3F. In some embodiments the laser is applied through the channels 402 shown in FIG. 3E. The channels 402 direct the laser to contact the clamping plate 356 over the micro-LEDs 104. In some embodiments of the pattern 360, the laser may start near the exterior edges of the clamping plate 356 and continue towards the center of the clamping plate 356 in a rectangular pattern. The laser may start the pattern 360 towards the exterior of the clamping plate 356 because the micro-LEDs 104 near the exterior of the clamping plate 356 may be sacrificial. When the pattern 360 of the laser is initiated near the exterior of the clamping plate 356, the micro-LEDs 104 near the center of the clamping plate 356, where the active array of the micro-LEDs 104 is located, are removed with less damage to the micro-LEDs 104. In some embodiments of the pattern 360, a symmetric pattern may be utilized to further reduce damage to the micro-LEDs 104. Although the pattern 360 is shown to be rectangular, the pattern 360 may be any regular or irregular shape.

The laser wavelength may be chosen based on the material of the plate 332 and the absorbance of the plate 332 material. The laser wavelength may be between 190 nm and 250 nm. In one embodiment, the laser wavelength may be 248 nm. The laser fluence may be between 0.6 J/cm² and 1.1 J/cm². Additionally, the scanning frequency of the laser may range from 5 Hz to 40 Hz. In certain embodiments, the laser vaporizes the interface between the micro-LEDs 104 and the plate 332. For example, the laser can vaporize the interface between a micro-LED 104 and a plate 332 that includes sapphire.

In operation 260, the clamp 350 and the bonder stage 330 and bonder head 334 are removed. The backplane 102 after operation 260 is shown in FIGS. 3G-3H. During operation 260, the vacuum suction on the vacuum chuck 358 is decreased or turned off. The clamping plate 356 is then removed from the bonder head 334. In some embodiments, after the removal of the clamp 350, the bonder stage 330 and the bonder head 334 are removed. In other embodiments, the bonder stage 330 and the bonder head 334 are removed simultaneously with the clamp 350.

In FIG. 3G, all of the micro-LEDs 104 were removed from the plate 332. In some embodiments, after operation 260, the plate 332 may undergo further processing to apply new micro-LEDs 104, and the method 200 may be repeated with a new backplane 102. In FIG. 3H, the micro-LEDs 104x were transferred to the backplane 102, but the micro-LEDS 104y remain on the plate 332. In some embodiments, after operation 260, the plate 332 may be aligned above a new backplane 102, and the method 200 may be repeated.

In operation 270, SI structures 110 are formed on the backplane 102. The SI structures 110 are disposed on each side of the micro-LED 104, this creates a well 113 of a sub-pixel 112. The backplane 102 after operation 270 is shown in FIG. 3I.

In operation 280, color conversion material 114 is deposited into a well 113. As shown in FIG. 3J, a red color conversion material 114a is deposited in a well 113. The color conversion material 114 is then cured. Operation 280 is repeated until color conversion material 114 is deposited in the well 113 of the second sub-pixel 112b and the well 113 of the third sub-pixel 112c. For example, a blue color conversion material 114b may be deposited in a well 113 of the second sub-pixel 112b and the blue color conversion material 114b is cured, and a green color conversion material 114c may be deposited in a well 113 of the third sub-pixel 112c and the green color conversion material 114c is cured. The color conversion material 114 is cured by turning on the micro-LEDs or by exposure to a UV-light. An encapsulation layer 122 is then disposed over a top surface of the SI structures 110 and the sub-pixel 112. In certain embodiments, micro-lenses 128 may be disposed on the encapsulation layer 122 and over each of the wells. In other embodiments, a passivation layer 126 may be disposed on the micro-lenses 128. The pixel 100 may undergo further processing to form a pixel 100 as seen in FIG. 1 to include the encapsulation layer 122, the micro-lenses 128, and the passivation layer 126.

While the foregoing is directed to embodiments of the present disclosure, other and further embodiments of the disclosure may be devised without departing from the basic scope thereof, and the scope thereof is determined by the claims that follow.

1. A device, comprising:
a backplane, the backplane having a plurality of backplane electrodes, each backplane electrode comprising a first material and each backplane electrode contacts the backplane;
a plurality of micro-LEDs having a plurality of micro-LED electrodes, each micro-LED electrode comprising a second material and each micro-LED electrode contacts each micro-LED, wherein each micro-LED electrode is bonded to each backplane electrode with an alloy of the first material and the second material therebetween, the alloy contacts each micro-LED electrode and each backplane electrode; and
a plurality of subpixel isolation (SI) structures formed over the backplane, adjacent SI structures having a micro-LED disposed therebetween.

2. The device of claim 1, wherein the first material includes gold, indium, tin, silver, aluminum, platinum, or combinations thereof.

3. The device of claim 1, wherein the second material includes gold, silver, aluminum, platinum, indium, or combinations thereof.

4. The device of claim 1, wherein the alloy has a ratio of the first material to the second material and the ratio of first material to second material is about 1:3 to about 3:1.

5. A method, comprising:
aligning a transfer piece with a receiving piece, the receiving piece comprising:
a bonder stage;
a backplane disposed on the bonder stage; and
backplane electrodes disposed on the backplane;
heating the transfer piece to a first temperature and heating the receiving piece to a second temperature;
applying pressure to the transfer piece, the transfer piece comprising:
a bonder head;
a plate coupled to the bonder head;
micro-LEDs coupled to the plate; and
micro-LED electrodes coupled to each of the micro-LEDs;
alloying the backplane electrodes with the micro-LED electrodes;
decreasing the second temperature;
applying a clamp to the transfer piece;
applying a laser to the clamp; and
vaporizing an interface between the plate and the micro-LEDs.

6. The method of claim 5, further comprising:
removing the clamp;
forming subpixel isolation (SI) structures on the backplane wherein the SI structures form a well of a sub-pixel; and
forming micro-lenses over the micro-LEDs.

7. (canceled)

8. (canceled)

9. The method of claim 5, wherein the first temperature is about 40° C. and about 80° C.

10. The method of claim 5, wherein the second temperature is about 150° C. and about 300° C.

11. The method of claim 5, wherein the plate is comprised of silicon (Si), silicon carbide (SiC), aluminum nitride (AlN), gallium nitride (GaN), sapphire, or any combination thereof.

12. The method of claim 5, wherein the pressure is about 100 psi and about 600 psi.

13. The method of claim 5, wherein the second temperature is decreased to the first temperature.

14. The method of claim 13, wherein the decreasing the second temperature is performed according to a step function or a linear function.

15. The method of claim 5, wherein the laser is applied in a symmetric pattern.

16. The method of claim 15, wherein the symmetric pattern is initiated at or near an exterior of the clamp.

17. The method of claim 5, wherein the vaporizing an interface layer between the plate and the micro-LEDs separates the micro-LEDs from the plate.

18. (canceled)

19. The method of claim 13, wherein the second temperature is decreased via cooling channels disposed in the bonder stage.

20. A method, comprising:
aligning a transfer piece with a receiving piece, the receiving piece comprising:
a bonder stage;
a backplane disposed on the bonder stage; and
backplane electrodes disposed on the backplane, each backplane electrode comprising a first material;
heating the transfer piece to a first temperature and heating the receiving piece to a second temperature;
applying pressure to the transfer piece, the transfer piece comprising:
a bonder head;
a plate coupled to the bonder head;
micro-LEDs coupled to the plate; and
micro-LED electrodes coupled to each of the micro-LEDs, the micro-LED electrodes comprising a second material;
forming an alloy of the first material and the second material between the backplane electrodes and the micro-LED electrodes;
decreasing the second temperature;
applying a clamp to the transfer piece;
applying a laser to the clamp; and
vaporizing an interface between the plate and the micro-LEDs.

21. The device of claim 1, wherein a plurality of micro-lenses disposed the plurality of micro-LEDs.

22. The device of claim 21, further comprising a passivation layer disposed over the plurality of micro-lenses.

23. The method of claim 20, further comprising:
removing the clamp;
forming subpixel isolation (SI) structures on the backplane wherein the SI structures form a well of a sub-pixel; and
forming micro-lenses over the micro-LEDs.
